(19) United States
(12) Patent Application Publication
(10) Pub. No.: US 2025/0075976 A1
(43) Pub. Date: Mar. 6, 2025

(54) INJECTOR MOUNTING APPARATUS OF FURNACE

(71) Applicant: Shanghai Huali Microelectronics Corporation, Shanghai (CN)

(72) Inventor: Jianyong Wang, Shanghai (CN)

(73) Assignee: Shanghai Huali Microelectronics Corporation, Shanghai (CN)

(21) Appl. No.: 18/631,177

(22) Filed: Apr. 10, 2024

(30) Foreign Application Priority Data
Aug. 30, 2023 (CN) 202311112365.9

(51) Int. Cl. F27B 5/16; H01L 21/67

(52) U.S. Cl. CPC F27B 5/16; H01L 21/67109

(57) ABSTRACT

The present application provides an injector mounting apparatus of a furnace, wherein a first injector in the furnace has a main injector pipe. The injector mounting apparatus includes a first mounting component. The first mounting component has an injector mounting hole for the first injector to pass through and be disposed therein, a first edge on a side of the main injector pipe close to the inner side surface of the process tube abuts on a second edge on a side of the injector mounting hole close to the inner side surface of the process tube, and there is a first spacing between the second edge and an outer side face of the first mounting component. A flange is disposed at the bottom of the process tube, and the first mounting component is mounted on the flange by means of a first fixing member.

### CROSS-REFERENCE TO RELATED APPLICATIONS

This application claims the priority to Chinese patent application No. 202311112365.9 filed on Aug. 30, 2023, the disclosure of which is incorporated herein by reference in its entirety.

### TECHNICAL FIELD

The present application relates to a semiconductor integrated circuit manufacturing device, in particular to an injector mounting apparatus of a furnace.

### BACKGROUND

A semiconductor gate process always uses polysilicon (poly) as a carrier. In subsequent development of a 40 nm technology, an amorphous body is derived, and is applied widely as a basic structural material in a MEMS due to a unique conductive characteristic and an advantage of easy implementation of a self-alignment process thereof.

A basic principle of an LPCVD process for depositing polysilicon is thermal decomposition of silane (SiH4): SiH4→Si (solid)+H2 (gas). Under a pressure of 13-133.32 pa and at a temperature of 600° C., a mean free path of gas molecules reaches an order of magnitude of nearly one millimeter. A uniform polysilicon thin film can be obtained on each silicon wafer by using a polysilicon thin film produced by the LPCVD process.

An LPCVD device used in a poly process technology node is a furnace, which usually further has a dry clean function capable of automatically cleaning a poly coating. An SiH4 gas is used in the furnace. After arriving at a worktable from a gas pipe, the SiH4 gas is required to be introduced into a process tube of the furnace through an injector mounted on the worktable. The SiH4 can be uniformly injected into the process tube, thereby achieving uniform growth of a polysilicon thin film. As the process tube is very long and can achieve the growth of a plurality of wafers at the same time, some injectors are long injectors, which are flat in shape. In the prior art, the injector is directly fixed by means of a top thread and the gas pipe, and sealed by disposing a sealing ring (o-ring) at a connection position. The existing injector, after mounted, is prone to cause adhesion between the injector and the inner surface of the process tube. The poly coating may remain at an adhesion position, easily causing poly peeling during the production and thereby making a product discarded.

Referring to FIG. 1, which is a schematic diagram of a sectional structure of an existing furnace, the existing furnace includes:
a housing 101, which is usually formed using a stainless steel material, wherein the interior of the housing 101 is vacuumized by means of a pump (not shown).

The process tube 102 is usually composed of a quartz material and is disposed inside the housing 101.

A wafer boat 103 is used to place a plurality wafer 104, and can be moved by means of a movement apparatus 105.

FIG. 1 also shows an injector 106, which is a long injector. The injector 106 includes a vertical main pipe 106a and a transverse pipe 106b at the bottom. In the process, the main pipe 106a is used to provide a required process gas such as silane for each wafer 104 in the wafer boat 103. Therefore, the main pipe 106a is required to extend from the bottom upward to a top surface of a top wafer along an inner side of an inner side face of the process tube 102.

A first side of the transverse pipe 106b and the bottom of the main pipe 106a are connected and form an elbow. The transverse pipe 106b passes through the housing 101, and is sealed by means of a sealing ring 107 and fixed by means of a top screw 108, to a gas pipe 109 outside the housing 101.

As can be seen from FIG. 1, the main pipe 106a of the injector 106 extends a longer distance along the inner side surface of the process tube 102. A spacing between the main pipe 106a of the injector 106 and the inner side surface of the process tube 102 cannot be ensured, easily causing adhesion between the main pipe 106a of the injector 106 and the inner side surface of the process tube 102.

### BRIEF SUMMARY

According to some embodiments in this application, a process tube and a plurality of first injectors are disposed in the furnace.

An internal space of the process tube is cylindrical in shape.

Each of the first injectors has a main injector pipe, which is located inside an inner side surface of the process tube and extends from the bottom to the top along the inner side surface of the process tube.

The injector mounting apparatus includes a first mounting component.

The first mounting component has an injector mounting hole for the first injector to pass through and be disposed therein, a first edge on a side of the main injector pipe of the first injector close to the inner side surface of the process tube abuts on a second edge on a side of the injector mounting hole close to the inner side surface of the process tube, there is a first spacing between the second edge and an outer side face of the first mounting component, and the outer side face of the first mounting component is a side face close to the inner side surface of the process tube.

A flange is disposed at the bottom of the process tube, and the first mounting component is mounted on the flange by means of a first fixing member.

The outer side face of the first mounting component is located on an inner side of the inner side surface of the process tube or aligned with the inner side surface of the process tube, and a distance between the first edge and the inner side surface of the process tube is greater than or equal to the first spacing.

In some cases, the first injector further includes a second transverse injector pipe, and the bottom of the main injector pipe and a first side of the second transverse injector pipe are connected together to form a communicating first elbow.

The injector mounting hole includes a first vertical hole and a second transverse hole communicating with each other, and a second elbow is formed at a connection position between the first vertical hole and the second transverse hole.

The main injector pipe passes through and is disposed in the first vertical hole, and the second transverse injector pipe passes through and is disposed in the second transverse hole; the first elbow is located in the second elbow, and a second side of the second transverse injector pipe extends to the outside of the outer side face of the first mounting component.

In some cases, the injector mounting apparatus further includes a second mounting component.

An inner side face of the first mounting component is a side face away from the inner side surface of the process tube.

The second mounting component is mounted on the inner side face of the first mounting component by means of a second fixing member, and a first side face of the second mounting component is a side face in fixed contact with the inner side face of the first mounting component.

In some cases, the first vertical hole and the second elbow are formed by a combination of a first recess portion disposed on the inner side face of the first mounting component and a second recess portion disposed on the first side face of the second mounting component.

In some cases, a constituent material of the first injector includes quartz.

In some cases, a second side of the second transverse injector pipe and a gas pipe are sealed and fixedly connected.

In some cases, the second side of the second transverse injector pipe and the gas pipe are sealed using a sealing ring.

In some cases, the second side of the second transverse injector pipe and the gas pipe are fixed using a top thread.

In some cases, the first fixing member includes a first screw hole disposed on the flange, a first hole passing through the first mounting component, and a first screw, the first hole is aligned with the first screw hole, and the first screw passes through the first hole and is fastened in the first screw hole.

In some cases, a first extension portion is disposed on the first mounting component, and the first hole is disposed on and passes through the first extension portion.

In some cases, the second fixing member includes a second screw hole disposed on the first mounting component, a second hole passing through the second mounting component, and a second screw, the second hole is aligned with the second screw hole, and the second screw passes through the second hole and is fastened in the second screw hole.

In some cases, a wafer boat is disposed in the process tube and used for placing wafers.

Atop surface of the main injector pipe is located above a top surface of a top one of the wafers in the wafer boat.

In some cases, the number of the first injectors is two.

In some cases, a second injector is also disposed in the furnace, and the length of the second injector is less than that of the first injector.

In some cases, the first injector and the second injector are each connected to a gas pipe.

In the present application, the first mounting component is provided for the long first injector of the furnace, and the injector mounting hole is disposed in the first mounting component for the first injector to pass through and be disposed therein, i.e., pass through and be fixedly disposed therein. As such, the first edge on the side of the long main injector pipe of the first injector close to the inner side surface of the process tube abuts on the second edge on the side of the injector mounting hole close to the inner side surface of the process tube, and there is the first spacing between the second edge and the outer side face of the first mounting component. By fixing the first mounting component on the flange at the bottom of the process tube, with the outer side face of the first mounting component being located on the inner side of the inner side surface of the process tube or aligned with the inner side surface of the process tube, the distance between the first edge and the inner side surface of the process tube may be greater than or equal to the first spacing. It can be seen that, by adjusting the first spacing, the distance between the first edge and the inner side surface of the process tube can be adjusted. Therefore, in the present application, a spacing between a long injector and the inner side surface of the process tube is adjustable to prevent adhesion between the long injector and the inner side surface of the process tube, preventing film layer peeling caused by the adhesion and thereby improving the product yield.

### BRIEF DESCRIPTION OF THE DRAWINGS

FIG. 1 is a schematic diagram of a sectional structure of an existing furnace;

FIG. 2 is a schematic diagram of a sectional structure of a furnace according to embodiments of the present application;

FIG. 3 is an enlarged view of a mounted injector in FIG. 2;

FIG. 4 is a schematic structural diagram viewed from left to right along FIG. 2 where a first mounting component of an injector mounting apparatus of a furnace is mounted according to embodiments of the present application;

FIG. 5 is a schematic structural diagram viewed from left to right along FIG. 2 where a second mounting component of the injector mounting apparatus of a furnace is mounted according to embodiments of the present application; and

FIG. 6 is a top view where the second mounting component of the injector mounting apparatus of a furnace is mounted according to embodiments of the present application.

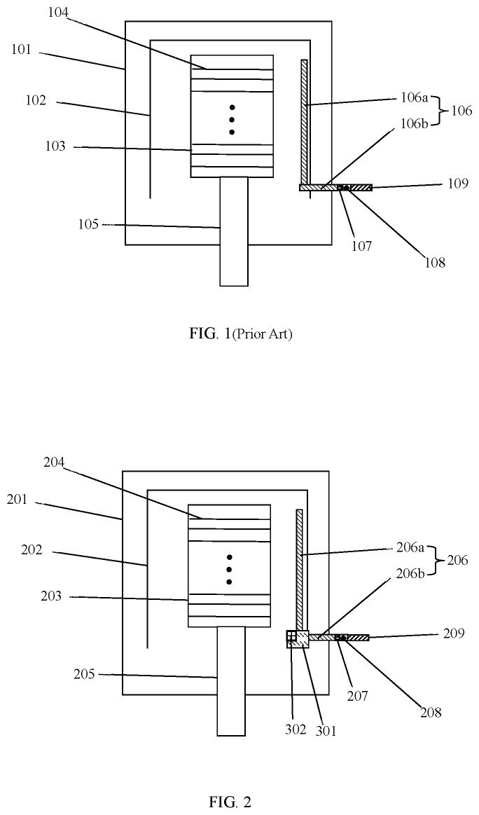

### DETAILED DESCRIPTION OF THE DISCLOSURE

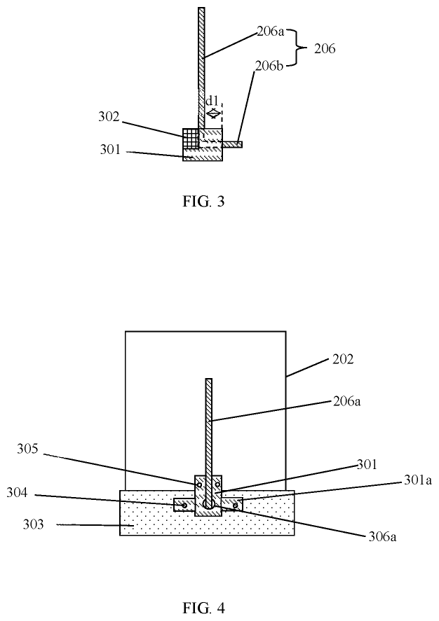

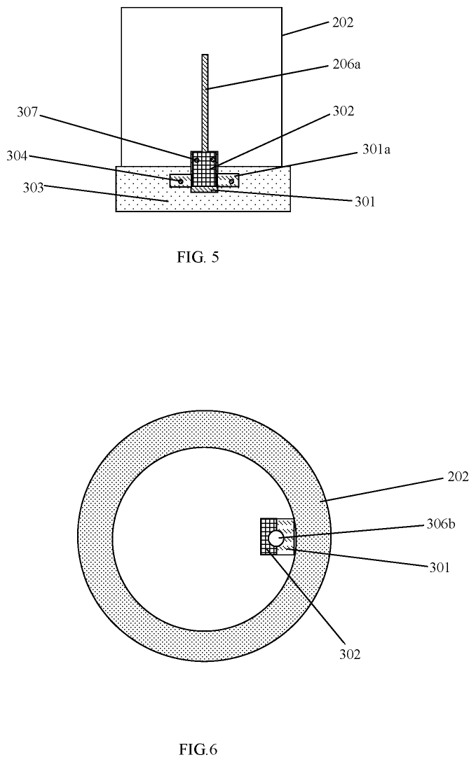

FIG. 2 is a schematic diagram of a sectional structure of a furnace according to embodiments of the present application. FIG. 3 is an enlarged view of a mounted injector in FIG. 2. FIG. 4 is a schematic structural diagram viewed from left to right along FIG. 2 where a first mounting component 301 of an injector mounting apparatus of a furnace is mounted according to embodiments of the present application. FIG. 5 is a schematic structural diagram viewed from left to right along FIG. 2 where a second mounting component 302 of the injector mounting apparatus of a furnace is mounted according to embodiments of the present application. FIG. 6 is a top view where the second mounting component 302 of the injector mounting apparatus of a furnace is mounted according to embodiments of the present application. Embodiments of the present application provide an injector mounting apparatus, wherein a process tube 202 and a plurality of first injectors 206 are disposed in the furnace.

The furnace further includes a housing 201, and the process tube 202 is disposed inside the housing 201.

An internal space of the process tube 202 is cylindrical in shape.

Each of the first injectors 206 has a main injector pipe 206a, which is located inside an inner side surface of the process tube 202 and extends from the bottom to the top along the inner side surface of the process tube 202.

The injector mounting apparatus includes a first mounting component 301.

The first mounting component 301 has an injector mounting hole for the first injector 206 to pass through and be disposed therein.

In the embodiments of the present application, the first injector 206 further includes a second transverse injector pipe 206b, and the bottom of the main injector pipe 206a and a first side of the second transverse injector pipe 206b are connected together to form a communicating first elbow.

The injector mounting hole includes a first vertical hole 306b and a second transverse hole 306a communicating with each other, and a second elbow is formed at a connection position between the first vertical hole 306b and the second transverse hole 306a. Referring to FIG. 3, the position of the injector mounting hole is as shown by a dashed line segment in the first mounting component 301. A top view of the first vertical hole 306b is as shown in FIG. 6, and a side view of the second transverse hole 306a is as shown in FIG. 4.

The main injector pipe 206a passes through and is disposed in the first vertical hole 306b, and the second transverse injector pipe 206b passes through and is disposed in the second transverse hole 306a; the first elbow is located in the second elbow, and a second side of the second transverse injector pipe 206b extends to the outside of the outer side face of the first mounting component 301.

A first edge on a side of the main injector pipe 206a of the first injector 206 close to the inner side surface of the process tube 202 abuts on a second edge on a side of the injector mounting hole close to the inner side surface of the process tube 202, there is a first spacing d1 between the second edge and an outer side face of the first mounting component 301, and the outer side face of the first mounting component 301 is a side face close to the inner side surface of the process tube 202.

Referring to FIG. 4, a flange 303 is disposed at the bottom of the process tube 202, and the first mounting component 301 is mounted on the flange 303 by means of a first fixing member.

The outer side face of the first mounting component 301 is located on an inner side of the inner side surface of the process tube 202 or aligned with the inner side surface of the process tube 202, and a distance between the first edge and the inner side surface of the process tube 202 is greater than or equal to the first spacing d1.

In the embodiments of the present application, referring to FIG. 4, the first fixing member includes a first screw hole disposed on the flange 303, a first hole passing through the first mounting component 301, and a first screw 304, the first hole is aligned with the first screw hole, and the first screw 304 passes through the first hole and is fastened in the first screw hole.

A first extension portion 301a is disposed on the first mounting component 301, and the first hole is disposed on and passes through the first extension portion 301a.

In the embodiments of the present application, the injector mounting apparatus further includes a second mounting component 302.

An inner side face of the first mounting component 301 is a side face away from the inner side surface of the process tube 202.

The second mounting component 302 is mounted on the inner side face of the first mounting component 301 by means of a second fixing member, and a first side face of the second mounting component is a side face in fixed contact with the inner side face of the first mounting component 301.

In the embodiments of the present application, referring to FIG. 4, the second fixing member includes a second screw hole 305 disposed on the first mounting component 301. Referring to FIG. 5, the second fixing member further includes a second hole passing through the second mounting component 302 and a second screw 307, the second hole is aligned with the second screw hole 305, and the second screw 307 passes through the second hole and is fastened in the second screw hole 305.

Referring to FIG. 6, in the embodiments of the present application, the first vertical hole 306b and the second elbow are formed by a combination of a first recess portion disposed on the inner side face of the first mounting component 301 and a second recess portion disposed on the first side face of the second mounting component. Such a split structure of the first mounting component 301 and the second mounting component 302 facilitates the mounting of the first injector 206. For example, referring to FIG. 4, the first mounting component 301 is mounted on the flange 303 first; at this time, the first vertical hole 306b is not closed, so it is convenient to pass and dispose the second transverse injector pipe 206b of the first injector 206 though and in the second transverse hole 306a.

Afterwards, referring to FIG. 5, the second mounting component 302 is mounted on the first mounting component 301, so that the first vertical hole 306b is completely closed, achieving the mounting of the first injector 206.

In the embodiments of the present application, a constituent material of the first injector 206 includes quartz.

Referring to FIG. 2, a second side of the second transverse injector pipe 206b and a gas pipe 209 are sealed and fixedly connected.

The second side of the second transverse injector pipe 206b and the gas pipe 209 are sealed using a sealing ring 207.

The second side of the second transverse injector pipe 206b and the gas pipe 209 are fixed using a top thread 208.

A wafer boat 203 is disposed in the process tube 202 and used for placing wafers 204.

Atop surface of the main injector pipe 206a is located above a top surface of a top one of the wafers 204 in the wafer boat 203.

In some embodiments, the number of the first injectors 206 is two.

A second injector is also disposed in the furnace, and the length of the second injector is less than that of the first injector 206.

The first injector 206 and the second injector are each connected to a gas pipe.

In some embodiments, the process tube 202 is used for producing polysilicon. A gas provided by the gas pipe connected to the first injector 206 and the second injector includes silane.

In the embodiments of the present application, the first mounting component 301 is provided for the long first injector 206 of the furnace, and the injector mounting hole is disposed in the first mounting component 301 for the first injector 206 to pass through and be disposed therein, i.e., pass through and be fixedly disposed therein. As such, the first edge on the side of the long main injector pipe 206a of the first injector 206 close to the inner side surface of the process tube 202 abuts on the second edge on the side of the injector mounting hole close to the inner side surface of the process tube 202, and there is the first spacing d1 between the second edge and the outer side face of the first mounting component 301. By fixing the first mounting component 301 on the flange at the bottom of the process tube 202, with the outer side face of the first mounting component 301 being located on the inner side of the inner side surface of the process tube 202 or aligned with the inner side surface of the process tube 202, the distance between the first edge and the inner side surface of the process tube 202 may be greater than or equal to the first spacing d1. It can be seen that, by adjusting the first spacing d1, the distance between the first edge and the inner side surface of the process tube 202 can be adjusted. Therefore, in the embodiments of the present application, a spacing between a long injector and the inner side surface of the process tube 202 is adjustable to prevent adhesion between the long injector and the inner side surface of the process tube 202, preventing film layer peeling caused by the adhesion and thereby improving the product yield.

The present application is described in detail above through specific embodiments, which, however, do not constitute limitations on the present application. Without departing from the principles of the present application, a person skilled in the art can also make many modifications and improvements, which should also be considered as the scope of protection of the present application.

What is claimed is:

1. An injector mounting apparatus of a furnace, wherein a process tube and a plurality of first injectors are disposed in the furnace;
an internal space of the process tube is cylindrical in shape;
each of the first injectors has a main injector pipe, which is located inside an inner side surface of the process tube and extends from the bottom to the top along the inner side surface of the process tube;
the injector mounting apparatus comprises a first mounting component;
the first mounting component has an injector mounting hole for the first injector to pass through and be disposed therein, a first edge on a side of the main injector pipe of the first injector close to the inner side surface of the process tube abuts on a second edge on a side of the injector mounting hole close to the inner side surface of the process tube, there is a first spacing between the second edge and an outer side face of the first mounting component, and the outer side face of the first mounting component is a side face close to the inner side surface of the process tube;
a flange is disposed at the bottom of the process tube, and the first mounting component is mounted on the flange by means of a first fixing member; and
the outer side face of the first mounting component is located on an inner side of the inner side surface of the process tube or aligned with the inner side surface of the process tube, and a distance between the first edge and the inner side surface of the process tube is greater than or equal to the first spacing.

2. The injector mounting apparatus of the furnace according to claim 1, wherein the first injector further comprises a second transverse injector pipe, and the bottom of the main injector pipe and a first side of the second transverse injector pipe are connected together to form a communicating first elbow;
the injector mounting hole comprises a first vertical hole and a second transverse hole communicating with each other, and a second elbow is formed at a connection position between the first vertical hole and the second transverse hole;
the main injector pipe passes through and is disposed in the first vertical hole, and the second transverse injector pipe passes through and is disposed in the second transverse hole; and
the first elbow is located in the second elbow, and a second side of the second transverse injector pipe extends to the outside of the outer side face of the first mounting component.

3. The injector mounting apparatus of the furnace according to claim 2, further comprising a second mounting component; wherein:
an inner side face of the first mounting component is a side face away from the inner side surface of the process tube; and
the second mounting component is mounted on the inner side face of the first mounting component by means of a second fixing member, and a first side face of the second mounting component is a side face in fixed contact with the inner side face of the first mounting component.

4. The injector mounting apparatus of the furnace according to claim 3, wherein the first vertical hole and the second elbow are formed by a combination of a first recess portion disposed on the inner side face of the first mounting component and a second recess portion disposed on the first side face of the second mounting component.

5. The injector mounting apparatus of the furnace according to claim 1, wherein a constituent material of the first injector comprises quartz.

6. The injector mounting apparatus of the furnace according to claim 4, wherein a second side of the second transverse injector pipe and a gas pipe are sealed and fixedly connected.

7. The injector mounting apparatus of the furnace according to claim 6, wherein the second side of the second transverse injector pipe and the gas pipe are sealed using a sealing ring.

8. The injector mounting apparatus of the furnace according to claim 6, wherein the second side of the second transverse injector pipe and the gas pipe are fixed using a top thread.

9. The injector mounting apparatus of the furnace according to claim 1, wherein the first fixing member comprises a first screw hole disposed on the flange, a first hole passing through the first mounting component, and a first screw, the first hole is aligned with the first screw hole, and the first screw passes through the first hole and is fastened in the first screw hole.

10. The injector mounting apparatus of the furnace according to claim 9, wherein a first extension portion is disposed on the first mounting component, and the first hole is disposed on and passes through the first extension portion.

11. The injector mounting apparatus of the furnace according to claim 3, wherein the second fixing member comprises a second screw hole disposed on the first mounting component, a second hole passing through the second mounting component, and a second screw, the second hole is aligned with the second screw hole, and the second screw passes through the second hole and is fastened in the second screw hole.

12. The injector mounting apparatus of the furnace according to claim 1, wherein a wafer boat is disposed in the process tube and used for placing wafers; and
a top surface of the main injector pipe is located above a top surface of a top one of the wafers in the wafer boat.

13. The injector mounting apparatus of the furnace according to claim 12, wherein a number of the first injectors is two.

14. The injector mounting apparatus of the furnace according to claim 13, wherein a second injector is also disposed in the furnace, and a length of the second injector is less than that of the first injector.

15. The injector mounting apparatus of the furnace according to claim 14, wherein the first injector and the second injector are each connected to a gas pipe
